(19) United States
(12) Patent Application Publication
(10) Pub. No.: US 2026/0009124 A1
(43) Pub. Date: Jan. 8, 2026

(54) FILM FORMING METHOD AND FILM FORMING APPARATUS

(71) Applicant: Tokyo Electron Limited, Tokyo (JP)

(72) Inventors: Yusuke SUZUKI, Yamanashi (JP); Munehito KAGAYA, Tokyo (JP)

(21) Appl. No.: 19/324,794

(22) Filed: Sep. 10, 2025

Related U.S. Application Data
(63) Continuation of application No. PCT/JP2024/008427, filed on Mar. 6, 2024.

(30) Foreign Application Priority Data
Mar. 20, 2023 (JP) 2023-044492

(51) Int. Cl. C23C 16/04; C23C 16/34; C23C 16/455; H01J 37/32; H01L 21/02

(52) U.S. Cl. CPC C23C 16/045; C23C 16/345; C23C 16/45534; C23C 16/45542; H01J 37/32449; H01L 21/0217; H01L 21/02274; H01L 21/0228; H01J 2237/332; H01J 2237/3387

(57) ABSTRACT

A film forming method includes forming a silicon nitride film in a recess in a substrate surface. Forming of the silicon nitride film includes: supplying an adsorption-inhibiting gas for inhibiting adsorption of a silicon-containing gas to the substrate surface in a form of a plasma; supplying the silicon-containing gas to the substrate surface; and supplying a nitriding gas for nitriding an adsorbate of the silicon-containing gas to the substrate surface in a form of a plasma. Nitriding gas contains N₂ gas. Forming of the silicon nitride film includes supplying an adsorption-promoting gas for promoting adsorption of the silicon-containing gas to the substrate surface. Performing a process: including supplying of the adsorption-inhibiting gas; supplying of the silicon-containing gas; and supplying of the nitriding gas one or more times, and performing supplying of the adsorption-promoting gas one or more times are performed a plurality of times repeatedly.

### CROSS-REFERENCE TO RELATED APPLICATIONS

This application is a continuation application of International Application No. PCT/JP2024/008427, filed on Mar. 6, 2024, and designating the U.S., which is based upon and claims priority to Japanese Patent Application No. 2023-044492, filed on Mar. 20, 2023, the entire contents of which are incorporated herein by reference.

### BACKGROUND

### Technical Field

The present disclosure relates to a film forming method and a film forming apparatus.

### Background Art

Japanese Patent Application Laid-Open Publication No. 2018-10950 and Japanese Patent Application Laid-Open Publication No. 2022-111765 disclose a technique for embedding a silicon nitride film in a recess in a substrate surface. Japanese Patent Application Laid-Open Publication No. 2018-10950 recites a step of supplying NH₃ gas to a substrate surface to form an adsorption site composed of an NH₂ group in the entirety of a recess, a step of supplying Cl₂ gas to the substrate surface to form a non-adsorption site in an upper part of the recess and leave the adsorption site in place in a lower part of the recess, and a step of supplying a silicon-containing gas to the substrate surface. Japanese Patent Application Laid-Open Publication No. 2022-111765 recites use of not only a halogen gas but also a non-halogen gas as adsorption-inhibiting gases.

Japanese Patent Application Laid-Open Publication No. 2020-113743 discloses a technique for forming a silicon nitride film on a substrate surface. As a specific example, Japanese Patent Application Laid-Open Publication No. 2020-113743 recites repeatedly performing a step of supplying dichlorosilane (DCS: SiH₂Cl₂) gas to the substrate surface, a step of supplying a modifying gas composed of H₂ gas and N₂ gas to the substrate surface in the form of a plasma, and a step of supplying a nitriding gas composed of NH₃ gas to the substrate surface without forming a plasma thereof, in a stated order.

### SUMMARY

The film forming method according to one embodiment of the present disclosure includes forming a silicon nitride film in a recess in a substrate surface. The forming of the silicon nitride film includes supplying an adsorption-inhibiting gas for inhibiting adsorption of a silicon-containing gas to the substrate surface in a form of a plasma, supplying the silicon-containing gas to the substrate surface, and supplying a nitriding gas for nitriding an adsorbate of the silicon-containing gas to the substrate surface in a form of a plasma. The nitriding gas contains N₂ gas. The forming of the silicon nitride film includes supplying an adsorption-promoting gas for promoting adsorption of the silicon-containing gas to the substrate surface. Performing a process including: the supplying of the adsorption-inhibiting gas; the supplying of the silicon-containing gas; and the supplying of the nitriding gas one or more times, and performing the supplying of the adsorption-promoting gas one or more times are performed a plurality of times repeatedly.

### BRIEF DESCRIPTION OF THE DRAWINGS

FIG. 1 is a cross-sectional view showing a film forming method according to one embodiment.

FIG. 2 is a flowchart showing an example of a film forming step;

FIG. 3 is a diagram showing film forming conditions in Examples 1 to 4;

FIG. 4 is a diagram showing film forming conditions in Examples 5 to 9;

FIG. 5 is an SEM image of a substrate obtained under the film forming condition in Example 8;

FIG. 6 is a diagram showing the relationship between WER and depth of silicon nitride films obtained under the film forming conditions in Examples 1 and 2;

FIG. 7 is a diagram showing the relationship between GPC and depth of silicon nitride films obtained under the film forming conditions in Examples 1 to 4;

FIG. 8 is a diagram showing the relationship between GPC and depth of silicon nitride films obtained under the film forming conditions in Examples 5 to 7;

FIG. 9 is a diagram showing the relationship between GPC and depth of silicon nitride films obtained under the film forming conditions in Examples 6, 8 and 9;

FIG. 10 is a diagram showing the relationship between GPC and depth of silicon nitride films obtained under the film forming conditions in Examples 1, 2 and 8;

FIG. 11 is a diagram showing the relationship between GPC_{X-250} and depth of silicon nitride films obtained under the film forming conditions in Examples 1, 2, and 8;

FIG. 12 is a diagram showing the relationship between WER₀ and GPC₀₋₂₅₀ of silicon nitride films obtained under the film forming conditions in Examples 1, 2, and 8; and

FIG. 13 is a cross-sectional view showing a film forming apparatus according to an embodiment.

### DETAILED DESCRIPTION OF THE INVENTION

Embodiments of the present disclosure will be described below with reference to the drawings. In the drawings, the same or corresponding components are denoted by the same reference numerals and the description thereof may be omitted.

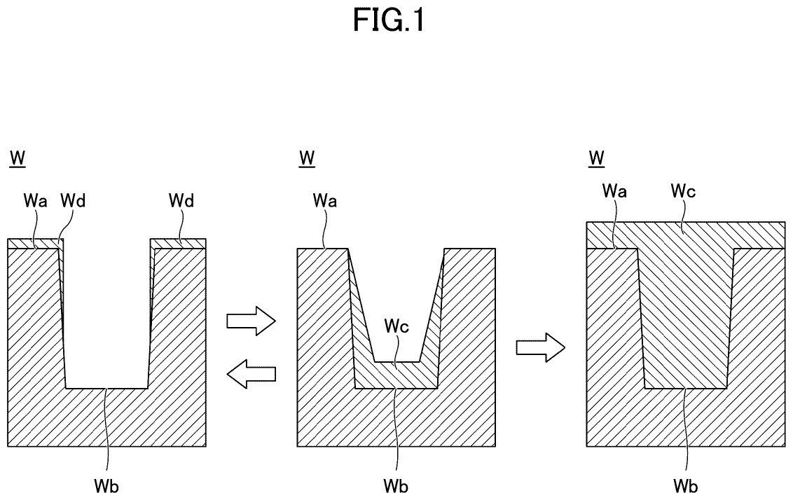

Referring to FIG. 1, a film forming method according to one embodiment will be described. The film forming method includes a step of forming a silicon nitride film Wc in a recess Wb in a substrate surface Wa as shown in FIG. 1. This step is hereinafter also referred to as a film forming step. The substrate W is a silicon wafer in the present embodiment. However, it may be a compound semiconductor wafer. The substrate W has the recess Wb in the substrate surface Wa. The recess Wb is a trench in the present embodiment. However, it may be a via hole.

In the film forming step, the silicon nitride film Wc is filled into the recess Wb while maintaining a letter-V cross-sectional shape in order to inhibit generation of voids and seams. The film forming step includes a step of supplying an adsorption-inhibiting gas to the substrate surface Wa in order to maintain the letter-V cross-sectional shape. The adsorption-inhibiting gas inhibits adsorption of a silicon-containing gas.

The adsorption-inhibiting gas adsorbs to the substrate surface Wa. An adsorbate Wd of the adsorption-inhibiting gas forms a non-adsorption site that is for the silicon-containing gas to be inhibited from adsorbing to. The non-adsorption site is formed by the adsorbate Wd adsorbing to an adsorption site that the silicon-containing gas would otherwise adsorb to. The density of the non-adsorption site becomes lower as the depth from the substrate surface Wa becomes greater. As a result, the greater the depth from the substrate surface Wa, the easier it is for adsorption of the silicon-containing gas to proceed. Therefore, the silicon nitride film Wc can be filled into the recess Wb while maintaining the letter-V cross-sectional shape. The density distribution in the non-adsorption site is controlled by the supply time of the adsorption-inhibiting gas and the like.

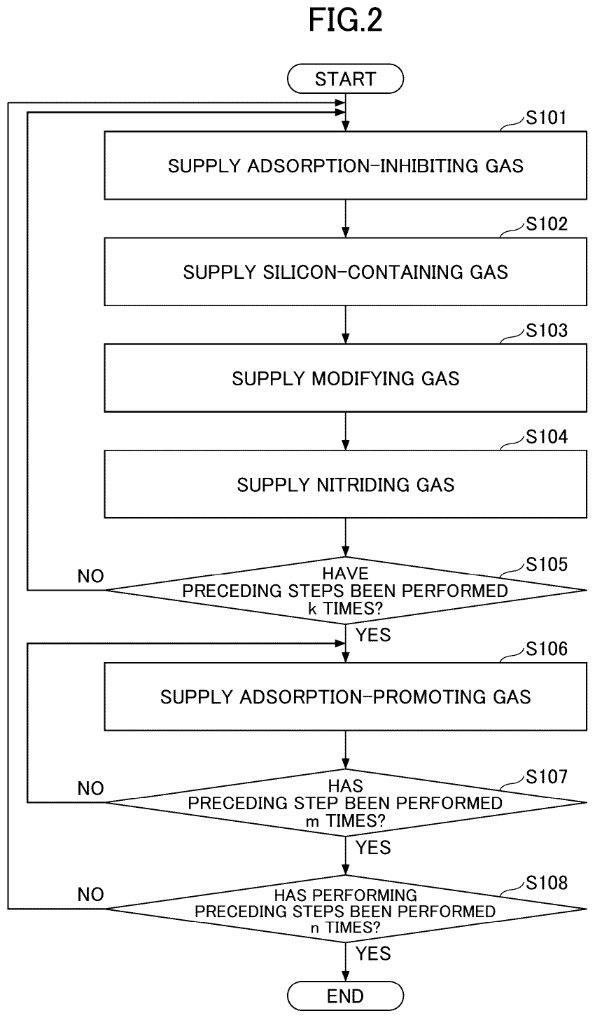

Referring to FIG. 2, an example of the film forming step will be described. As shown in FIG. 2, the film forming step includes, for example, steps S101 to S108. In FIG. 2, k and m are integers equal to or greater than 1, and n is an integer equal to or greater than 2. The order of steps S101 to S108 is not limited to the order shown in FIG. 2. Note that all steps S101 to S108 do not need not be performed. For example, step S103 may be omitted. In addition, there may be steps not shown. The steps not shown include, for example, supply of a purge gas and gas flow rate adjustment. The gas remaining in the processing vessel is replaced with the purge gas.

The technique of the present disclosure uses N₂ gas in the supplying of a nitriding gas (step S104), as will be described in detail later. As a result, the silicon nitride film Wc can have an improved film quality and an improved wet etching resistance, compared with a case where NH₃ gas is used as the nitriding gas. However, as will be described in detail later, the embeddability decreases due to use of N₂ gas as the nitriding gas. Therefore, supplying of the adsorption-promoting gas (step S106) is performed before supplying of the adsorption-inhibiting gas (step S101) is performed again. Thus, the letter-V cross-sectional shape can be maintained and the embeddability can be improved.

Step S101 includes supplying the adsorption-inhibiting gas to the substrate surface Wa in the form of a plasma. The adsorption-inhibiting gas is adsorbed to the substrate surface Wa. The adsorbate Wd of the adsorption-inhibiting gas forms the non-adsorption site that is for the silicon-containing gas to be inhibited from adsorbing to. The density of the non-adsorption site becomes lower as the depth from the substrate surface Wa becomes greater. The density distribution in the non-adsorption site is controlled by the supply time of the adsorption-inhibiting gas and the like.

The adsorption-inhibiting gas includes, for example, at least one of halogen gas, non-halogen gas, or mixture gas of halogen gas and non-halogen gas. The halogen gas is, for example, F₂ gas, Cl₂ gas, or HF gas, and is preferably Cl₂ gas. The non-halogen gas is, for example, N₂ gas. Chlorine (Cl) or nitrogen (N) easily adsorbs to the adsorption site that the silicon-containing gas would adsorb to, and easily inhibits adsorption of the silicon-containing gas. The non-adsorption site is formed by, for example, chlorine (Cl) or nitrogen (N) adsorbing to the adsorption site that the silicon-containing gas would otherwise adsorb to.

The processing conditions in step S101 may be changed in accordance with the number of times the step S101 has been performed, and, for example, the supply time of the adsorption-inhibiting gas may be changed. In the earlier film forming step, the aspect ratio (depth/opening width) of the recess Wb is large, which requires the density difference in the non-adsorption site to be large in the depth direction of the recess Wb. Therefore, in the earlier film forming step, Cl₂ gas having a high adsorption inhibiting effect is supplied for a first set time as the adsorption-inhibiting gas. This facilitates maintaining the letter-V cross-sectional shape.

On the other hand, in the later film forming step, since the aspect ratio (depth/opening width) of the recess Wb is small, it is easy to maintain the letter-V cross-sectional shape even if the density difference in the non-adsorption site in the depth direction of the recess Wb is small. Therefore, in the later film forming step, the adsorption-inhibiting gas is supplied for a second set time. The second set time is equal to the first set time or shorter than the first set time. Thus, it is possible to improve the throughput while maintaining the letter-V cross-sectional shape.

Although not shown, step S101 may include a first step of supplying a mixture gas of halogen gas and non-halogen gas to the substrate surface Wa in the form of a plasma, and a second step of supplying only one of halogen gas or non-halogen gas to the substrate surface Wa in the form of a plasma. In this case, in step S101, the first step and the second step may be repeated alternately a plurality of times.

In the earlier film forming step, the partial pressure of the Cl₂ gas in the mixture gas may be set to be higher than the partial pressure of the N₂ gas, such that the adsorption inhibiting effect of the Cl₂ gas become relatively higher than the adsorption inhibiting effect of the N₂ gas. On the other hand, in the later film forming step, the partial pressure of the N₂ gas in the mixture gas may be set to be higher than the partial pressure of the Cl₂ gas, such that the adsorption inhibiting effect of the N₂ gas becomes relatively higher than the adsorption inhibiting effect of the Cl₂ gas. The supply time may be adjusted instead of or in addition to the partial pressure.

The conditions in step S101 are, for example, as follows.
Time: 0.05 seconds to 6 seconds;
RF power: 10 W to 500 W;
Pressure: 0.1 Torr (13.3 Pa) to 50 Torr (6.7 kPa); and
Temperature: 350° C. to 600° C.

Step S102 includes supplying the silicon-containing gas to the substrate surface Wa. As the depth from the substrate surface Wa increases, the density of the adsorbate Wd of the adsorption-inhibiting gas decreases and thus the density of a silicon-containing layer, which is the adsorbate of the silicon-containing gas, increases. Therefore, it is possible to fill the silicon nitride film Wc into the recess Wb while maintaining the letter-V cross-sectional shape, and to inhibit generation of voids and seams.

The silicon-containing gas needs only to contain silicon (Si), but it is preferable that the silicon-containing gas contains a halogen. The halogen may be, for example, chlorine (Cl), bromine (Br), or iodine (I). The silicon-containing gas may be, for example, dichlorosilane (DCS: SiH₂Cl₂) gas. The silicon-containing gas may be monochlorosilane (MCS: SiH₃Cl) gas, trichlorosilane (TCS: SiHCl₃) gas, silicon tetrachloride (STC: SiCl₄) gas, or hexachlorodisilane (HCDS: Si₂Cl₆) gas.

The conditions in step S102 are, for example, as follows.
Time: 1 second to 10 seconds;
Pressure: 0.1 Torr (13.3 Pa) to 50 Torr (6.7 kPa); and
Temperature: 350° C. to 600° C.

Step S103 includes supplying a modifying gas to the substrate surface Wa in the form of a plasma. The modifying gas modifies the silicon-containing layer. The silicon-containing layer contains a halogen in addition to silicon (Si), and the modifying gas removes halogen contained in the silicon-containing layer. Thus, dangling bonds of Si can be formed. As a result, the Si-containing layer can be activated, and nitridation of the Si-containing layer can be promoted. The modifying gas contains H₂ gas. The modifying gas may contain an inert gas in addition to the H₂ gas. The inert gas is a noble gas, such as Ar gas and the like, or N₂ gas. It is preferable to perform supplying of the modifying gas (step S103) after supplying of the silicon-containing gas (step S102) and before supplying of a nitriding gas (step S104).

The conditions in step S103 are, for example, as follows.
Time: 1 second to 10 seconds;
RF power: 100 W to 3 kW;
Pressure: 0.1 Torr (13.3 Pa) to 50 Torr (6.7 kPa); and
Temperature: 350° C. to 600° C.

Step S104 includes supplying a nitriding gas to the substrate surface Wa in the form of a plasma. The nitriding gas nitrides the silicon-containing layer. The nitriding gas contains N₂ gas. The nitriding gas may contain an inert gas in addition to N₂ gas. The inert gas is a noble gas, such as Ar gas and the like. Use of N₂ gas instead of NH₃ gas as the nitriding gas can improve the film quality of the silicon nitride film Wc and can improve the wet etching resistance.

The conditions in step S104 are, for example, as follows.
Time: 1 second to 10 seconds;
RF power: 100 W to 3 KW;
Pressure: 0.1 Torr (13.3 Pa) to 50 Torr (6.7 kPa); and
Temperature: 350° C. to 600° C.

In step S105, it is checked whether or not steps S101 to S104 have been performed a set number of times (k times). Although k is 1 in the present embodiment, it may be an integer of 2 or greater. When the number of times these steps have been performed has not reached k times, steps S101 to S104 are performed again. On the other hand, when the number of times the steps have been performed has reached k times, step S106 is performed.

Step S106 includes supplying an adsorption-promoting gas to the substrate surface Wa. The adsorption-promoting gas promotes adsorption of the silicon-containing gas. The adsorption-promoting gas may, but does not need to, be in the form of a plasma. Step S106 may include a step of supplying the adsorption-promoting gas to the substrate surface Wa without forming a plasma thereof, and a step of supplying the adsorption-promoting gas to the substrate surface Wa in the form of a plasma. By performing supplying of the adsorption-promoting gas (step S106) before performing supplying of the adsorption-inhibiting gas (step S101) again, it is possible to maintain the letter-V cross-sectional shape and improve the embeddability.

It is preferable that the adsorption-promoting gas contains an NH₂ group. The NH₂ group functions as an adsorption site for the silicon-containing gas to adsorb to. Use of the N₂ gas instead of NH₃ gas in step S104 reduces the number of NH₂ groups, unlike in the case of using NH₃ gas. In step S106, it is possible to cause the NH₂ groups to adsorb to the entire substrate surface Wa, and to cause them to adsorb to the recess Wb over the entire depth thereof. Therefore, by performing step S101 subsequently, it is possible to facilitate the adsorption site to have a density difference in the depth direction of the recess Wb, and to improve the embeddability.

The adsorption-promoting gas contains, for example, at least one selected from NH₃ gas, N₂H₄ gas, N₂H₂ gas, CH₃NHNH₂ gas, and CH₃NH₂ gas. The adsorption-promoting gas may contain a noble gas, such as Ar gas and the like, in addition to the gas containing the NH₂ group. The adsorption-promoting gas may contain a gas containing a hydrocarbon group, in addition to the gas containing the NH₂ group.

The conditions in step S106 are, for example, as follows.
Time: 1 second to 10 seconds;
RF power: 0 W to 500 W;
Pressure: 0.1 Torr (13.3 Pa) to 50 Torr (6.7 kPa); and
Temperature: 350° C. to 600° C.

In step S107, it is checked whether or not step S106 has been performed a set number of times (m times). Although m is 1 in the present embodiment, it may be an integer of 2 or greater. When the number of times the step has been performed has not reached m times, step S106 is performed again. When m is an integer of 2 or greater, and step S106 includes the step of supplying the adsorption-promoting gas to the substrate surface Wa without forming a plasma thereof, and the step of supplying the adsorption-promoting gas to the substrate surface Wa in the form of a plasma, these steps are performed repeatedly a plurality of times. On the other hand, when the number of times the step has been performed has reached m times, step S108 is performed.

In step S108, it is checked whether or not performing steps S101 to S104 the set number of times (k times) and performing step S106 the set number of times (m times) have been performed a set number of times (n times). “n” needs only to be an integer of 2 or greater. When performing these steps has not been performed n times, the process from step S101 is performed again. On the other hand, when performing these steps has been performed n times, the ongoing process is ended.

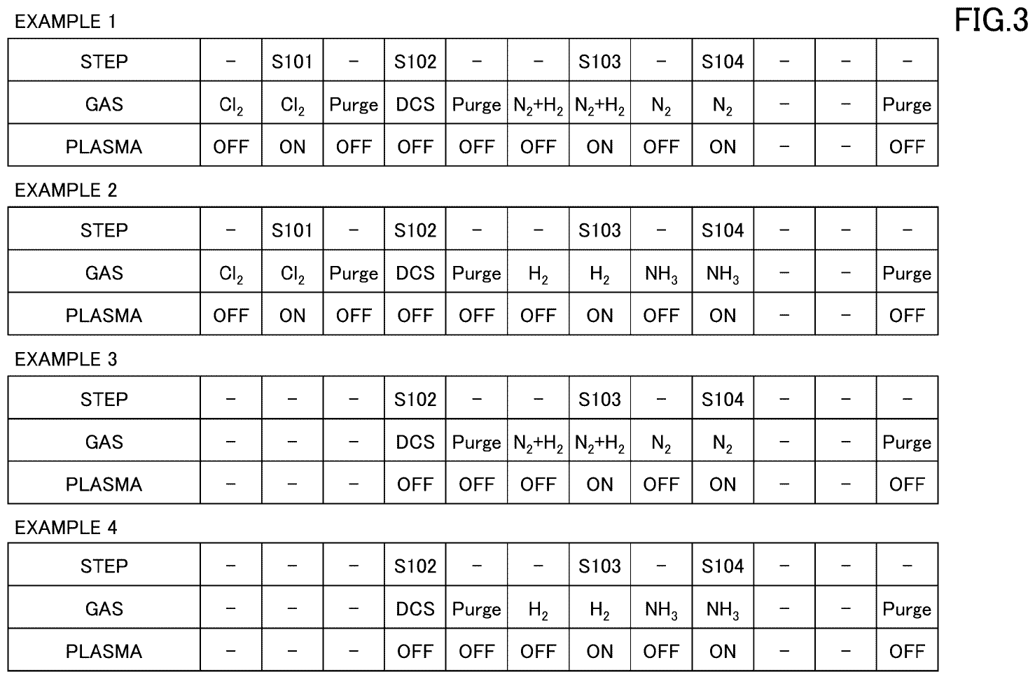

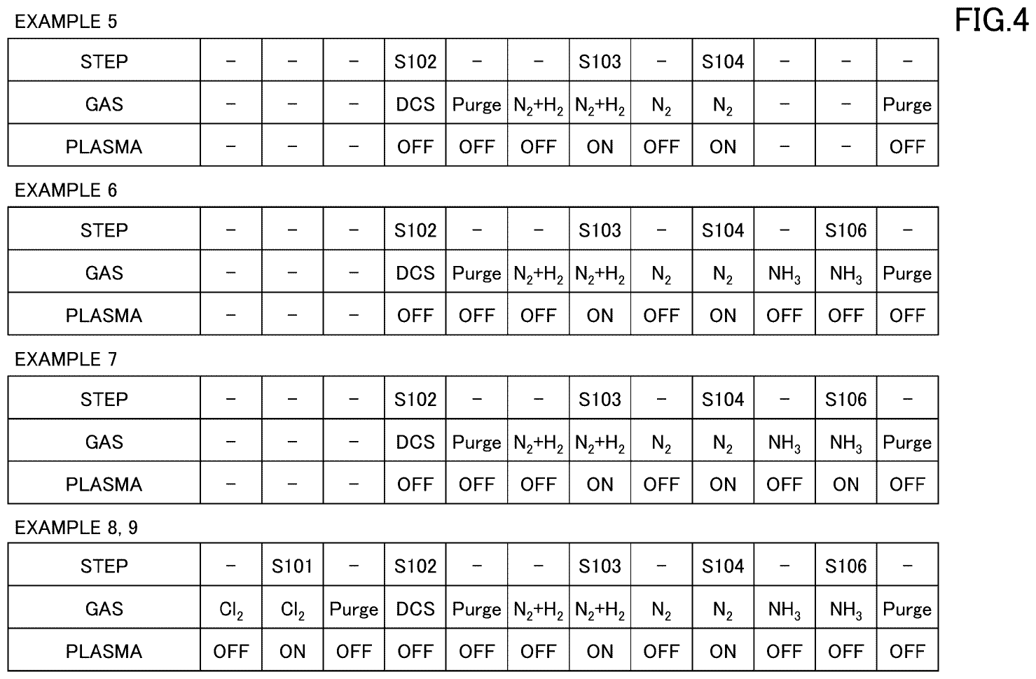

Experimental data will be described with reference to FIGS. 3 to 12. FIGS. 3 and 4 show the film forming conditions in Examples 1 to 9. In Examples 1 to 9, performing the steps shown in FIG. 3 or 4 in order from left to right was repeatedly performed n times. In Examples 1 to 9, k was 1, m was 1, and n was 300. In FIGS. 3 and 4, the step immediately before S101, the step immediately before S103, the step immediately before S104, and the step immediately before S106 are steps of adjusting the gas flow rate. In FIGS. 3 and 4, “plasma” being “ON” means that a plasma of the gas was formed, and “plasma” being “OFF” means that no plasma of the gas was formed. Examples 1 to 7 are Reference Examples, and Examples 8 and 9 are Examples. Representatively, an SEM image of a substrate W obtained under the film forming conditions in Example 8 is shown in FIG. 5. As shown in FIG. 5, according to Example 8, when filling the silicon nitride film Wc in the recess Wb, it was possible to inhibit generation of voids and seams.

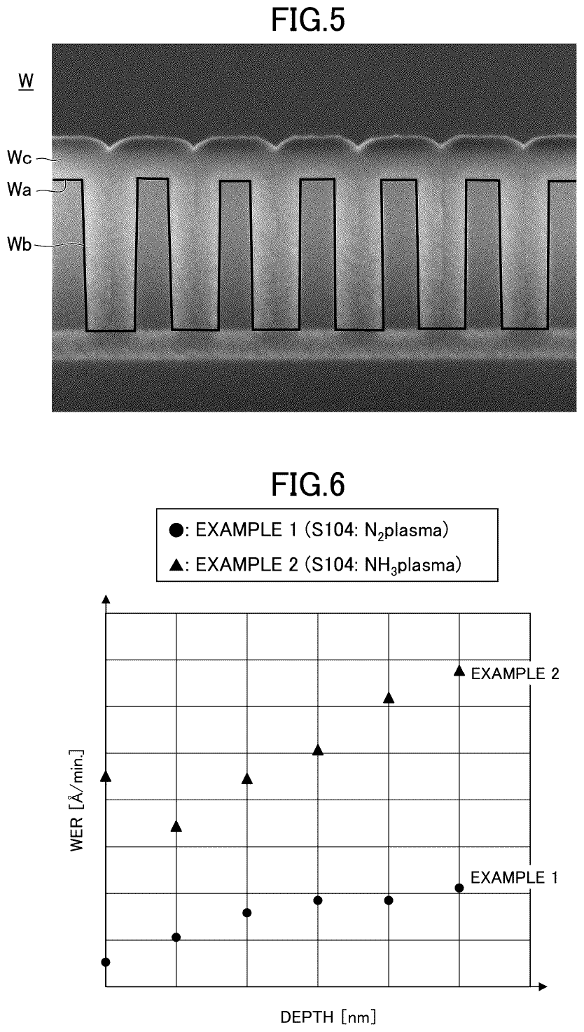

First, with reference to FIG. 6, the relationship between WER and depth of the silicon nitride films obtained under the film forming conditions in Examples 1 and 2 will be described. WER represents the etching rate of the silicon nitride film by dilute hydrofluoric acid (having an HF concentration of 0.5 vol %). The lower the WER, the better the film quality. N₂ gas was used as the nitriding gas in Example 1, whereas NH₃ gas was used as the nitriding gas in Example 2. It can be seen from FIG. 6 that it was possible to reduce the WER and improve the film quality by using N₂ gas instead of NH₃ gas as the nitriding gas.

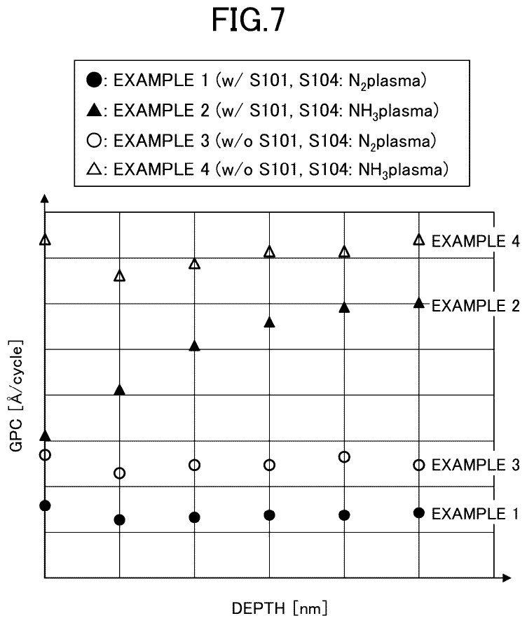

Next, with reference to FIG. 7, the relationship between GPC and depth of the silicon nitride films obtained under the film forming conditions of Examples 1 to 4 will be described. GPC represents the film forming rate of the silicon nitride film per cycle. A higher GPC at a greater depth makes the cross-sectional shape more like the letter V. In Example 3, the film forming step was performed under almost the same conditions as in Example 1 except that step S101 was omitted. In Example 4, the film forming step was performed under almost the same conditions as in Example 2 except that step S101 was omitted.

From a comparison between Example 2 and Example 4 in FIG. 7, it can be seen that in the case of using NH₃ gas as the nitriding gas, it is possible to obtain a letter-V cross-sectional shape by performing supplying of the adsorption-inhibiting gas (step S101) even without supplying of the adsorption-promoting gas (step S106). On the other hand, it can be seen from the results of Examples 1 and 3 that in the case of using N₂ gas as the nitriding gas, it is impossible to obtain a letter-V cross-sectional shape even by performing supplying of the adsorption-inhibiting gas (step S101).

From the results of FIGS. 6 and 7, it can be seen that in the case of using N₂ gas as the nitriding gas, the film quality of the silicon nitride film Wc can be improved and the wet etching resistance can be improved, but the embeddability is reduced, compared with the case of using NH₃ gas as the nitriding gas. Hence, by combining the use of N₂ gas as the nitriding gas and performing supplying of the adsorption-inhibiting gas, the technique of the present disclosure achieves both wet etching resistance and embeddability.

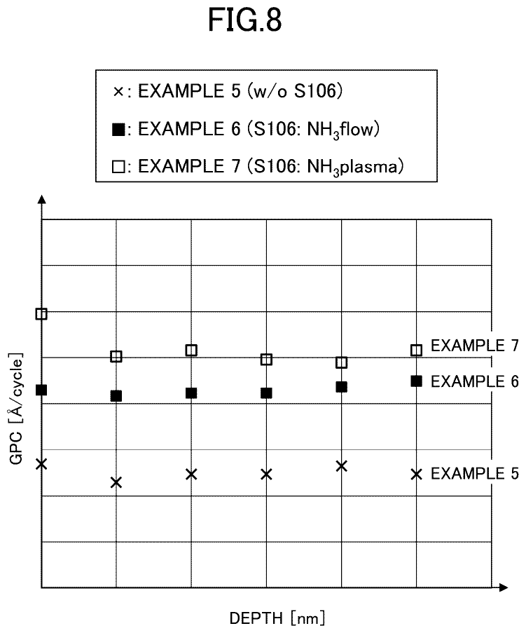

Next, referring to FIG. 8, the relationship between GPC and depth of the silicon nitride films obtained under the film forming conditions in Examples 5 to 7 will be described. In Example 5, supplying of the adsorption-promoting gas (step S106) was not performed, whereas in Examples 6 and 7, supplying of the adsorption-promoting gas (step S106) was performed. From FIG. 8, it can be seen that performing supplying of the adsorption-promoting gas (step S106) made the GPC higher. In all of Examples 5 to 7, the nitriding gas was N₂ gas. In all of Examples 5 to 7, supplying of the adsorption-inhibiting gas (step S101) was not performed.

From a comparison between Examples 6 and 7 in FIG. 8, it can be seen that it is possible to make the GPC higher and improve the throughput (the number of processed objects per unit time) by using the adsorption-promoting gas in the form of a plasma. On the other hand, in the case of not using the adsorption-promoting gas in the form of a plasma, it can be seen that the GPC can be made higher at a constant ratio regardless of the depth direction. It is advantageous to be able to make the GPC higher at a constant ratio, for the purpose of obtaining a letter-V cross-sectional shape by supplying of the adsorption-inhibiting gas (step S101).

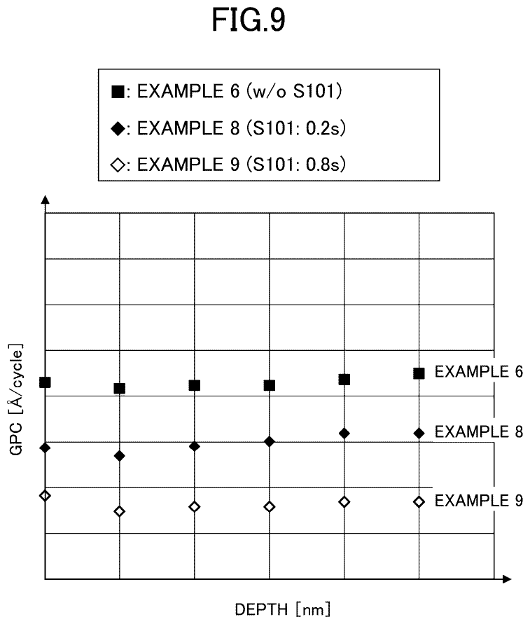

Next, referring to FIG. 9, the relationship between GPC and depth of the silicon nitride films obtained under the film forming conditions in Examples 6, 8, and 9 will be described. In Examples 6, 8, and 9, the film forming step was performed under the same conditions except for the adsorption-inhibiting gas supply time (the time taken in S101) as shown in FIG. 4. It can be seen from FIG. 9 that it is possible to make the GPC lower by increasing the adsorption-inhibiting gas supply time.

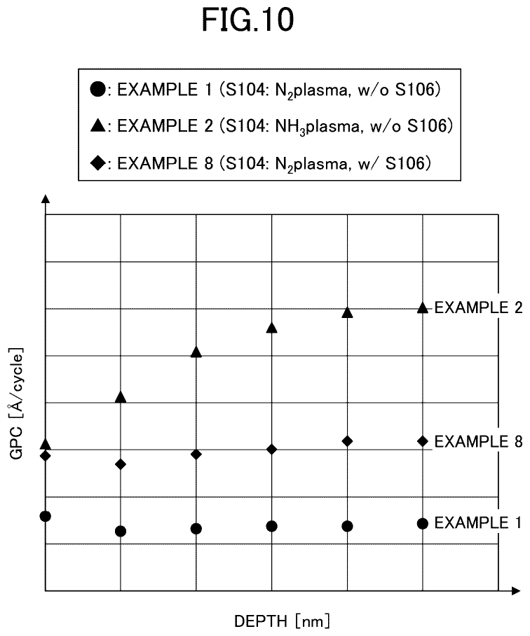

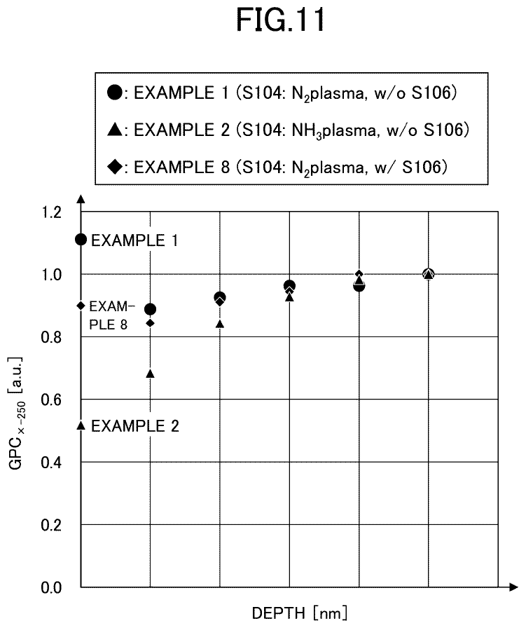

Next, referring to FIGS. 10 and 11, the relationship between GPC and depth of the silicon nitride films obtained under the film forming conditions in Examples 1, 2, and 8 will be described. In FIG. 11, GPC_{X-250} represents the ratio of the GPC at a depth of X nm when the GPC at a depth of 250 nm is regarded as being 1. It can be seen from FIGS. 10 and 11, and especially from FIG. 11, that in the case of using N₂ gas as the nitriding gas, it is possible to obtain a letter-V cross-sectional shape by performing supplying of the adsorption-inhibiting gas (step S101) and supplying of the adsorption-promoting gas (step S106).

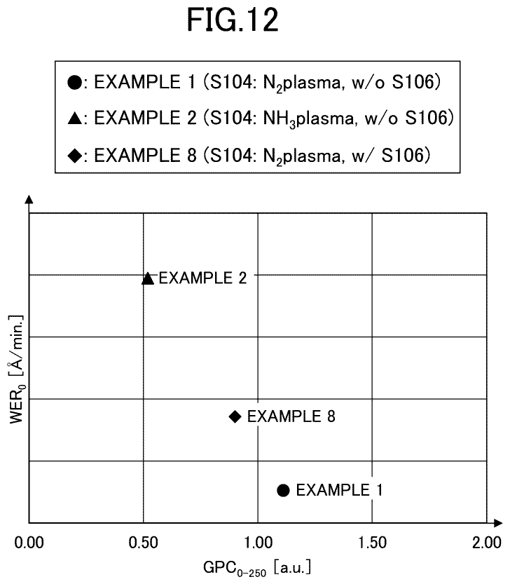

Next, referring to FIG. 12, the relationship between WER0 and GPC₀₋₂₅₀ of the silicon nitride films obtained under the film forming conditions in Examples 1, 2, and 8 will be described. In FIG. 12, WER₀ represents WER at a depth of 0 nm. In FIG. 12, GPC₀₋₂₅₀ represents the ratio of the GPC at a depth of 0 nm when the GPC at a depth of 250 nm is regarded as being 1. From FIG. 12, it can be seen that according to Example 8, a silicon nitride film having physical properties that were intermediate between those of Example 1 and those of Example 2 could be obtained.

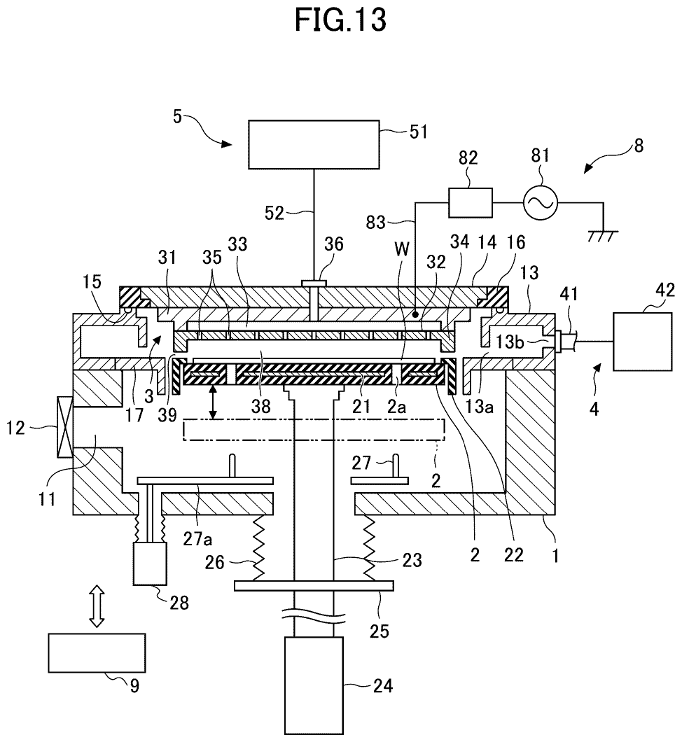

A film forming apparatus according to one embodiment will be described with reference to FIG. 13. The film forming apparatus includes a processing vessel 1, a holder 2, a showerhead 3, a gas exhaust part 4, a gas supply 5, a plasma forming part 8, a controller 9, and the like.

The processing vessel 1 is composed of a metal, such as aluminum and the like, and has a substantially cylindrical shape. The processing vessel 1 houses a substrate W. A loading/unloading opening 11 for loading or unloading the substrate W is formed in a side wall of the processing vessel 1. The loading/unloading opening 11 is opened and closed with a gate valve 12. An annular gas exhaust duct 13 having a rectangular cross-sectional shape is provided on the main body of the processing vessel 1. A slit 13a is formed in the gas exhaust duct 13 along the inner peripheral surface. A gas exhaust port 13b is formed in the outer wall of the gas exhaust duct 13. A top wall 14 is provided on the upper surface of the gas exhaust duct 13 via an insulator member 16 so as to close the upper opening of the processing vessel 1. A seal ring 15 airtightly seals the gap between the gas exhaust duct 13 and the insulator member 16. A partition member 17 partitions the interior of the processing vessel 1 into an upper part and a lower part when the holder 2 and a cover member 22 move upward to a processing position described later.

The holder 2 supports the substrate W horizontally in the processing vessel 1. The holder 2 has a disk shape having a size suited to the substrate W and is supported by a support member 23. The holder 2 is composed of a ceramic material, such as AlN and the like, or a metal material, such as aluminum, nickel alloy, and the like, and is internally embedded with a heater 21 for heating the substrate W. The heater 21 generates heat by being supplied with power from a heater power source (not shown). The substrate W is controlled to a predetermined temperature by the output power of the heater 21 being controlled based on a temperature signal from a thermocouple (not shown) provided near the upper surface of the holder 2. The holder 2 is provided with the cover member 22 composed of ceramics, such as alumina and the like, that covers the outer peripheral region of the upper surface and the side surface of the holder 2.

The support member 23 for supporting the holder 2 is provided on the bottom surface of the holder 2. The support member 23 extends from the center of the bottom surface of the holder 2 to under the processing vessel 1 by going through a hole formed in the bottom wall of the processing vessel 1, and its lower end is connected to a lifting mechanism 24. The lifting mechanism 24 moves the holder 2 upward and downward via the support member 23 between the processing position shown in FIG. 13 and a conveying position under the processing position, that is indicated by a dash-dotted line and at which the substrate W can be conveyed. A flange 25 is attached to a part of the support member 23 that is under the processing vessel 1. A bellows 26 is provided between the bottom surface of the processing vessel 1 and the flange 25. The bellows 26 partitions the atmosphere in the processing vessel 1 from the open air, and extends and contracts along with upward and downward movement of the holder 2.

Three support pins 27 (only two are shown) are provided near the bottom surface of the processing vessel 1 so as to project upward from a lifting plate 27a. The support pins 27 are moved upward and downward via the lifting plate 27a by a lifting mechanism 28 provided under the processing vessel 1. The support pins 27 are inserted into through holes 2a provided in the holder 2 when the holder 2 is at the conveying position, and can project from and retract into the top surface of the holder 2. By the support pins 27 being moved upward or downward, the substrate W is passed between a conveying mechanism (not shown) and the holder 2.

The showerhead 3 supplies gas into the interior of the processing vessel 1 in the form of a shower. The showerhead 3 is composed of metal, is provided so as to face the holder 2, and has a diameter approximately the same as that of the holder 2. The showerhead 3 has a main body 31 and a shower plate 32. The main body 31 is fixed to the top wall 14 of the processing vessel 1. The shower plate 32 is connected to the bottom of the main body 31. A gas diffusion space 33 is formed between the main body 31 and the shower plate 32. The gas diffusion space 33 is provided with a gas introduction hole 36 so as to penetrate the center of the top wall 14 of the processing vessel 1 and the main body 31. An annular projection 34 projecting downward is formed on the periphery of the shower plate 32. Gas discharge holes 35 are formed in a flat part inside the annular projection 34. When the holder 2 is at the processing position, a processing space 38 is formed between the holder 2 and the shower plate 32, and an annular gap 39 is formed between the upper surface of the cover member 22 and the annular projection 34 that have approached each other.

The gas exhaust part 4 exhausts gas from the interior of the processing vessel 1. The gas exhaust part 4 includes a gas exhaust pipe 41 connected to the gas exhaust port 13b and a gas exhaust mechanism 42 connected to the gas exhaust pipe 41 and including a vacuum pump, a pressure control valve, and the like. During processing, gas in the processing vessel 1 reaches the gas exhaust duct 13 through the slit 13a, travels through the gas exhaust pipe 41 from the gas exhaust duct 13, and is exhausted by the gas exhaust mechanism 42.

The gas supply 5 supplies various gases into the interior of the processing vessel 1. The gas supply 5 supplies various gases into the interior of the processing vessel 1 through, for example, the showerhead 3. The gas supply 5 includes a gas source 51 and a gas line 52. The gas source 51 includes, for example, a mass flow controller and a valve (both not shown). The gases to be supplied include the adsorption-inhibiting gas, the silicon-containing gas, the nitriding gas, the modifying gas, and the adsorption-promoting gas shown in FIG. 2. The gases to be supplied may include a purge gas. Various gases are introduced into the gas diffusion space 33 from the gas source 51 via the gas line 52 and the gas introduction hole 36.

The plasma forming part 8 forms a plasma of a gas supplied from the gas supply 5. The film forming apparatus is, for example, a capacitively coupled plasma apparatus, in which the holder 2 functions as a lower electrode and the showerhead 3 functions as an upper electrode. The holder 2 is grounded via a capacitor (not shown). However, the holder 2 may be grounded without a capacitor, and may be grounded via, for example, a circuit in which a capacitor and a coil are combined. The showerhead 3 is connected to a plasma forming part 8.

The plasma forming part 8 supplies high-frequency power (hereinafter, also referred to as “RF power”) to the showerhead 3. The plasma forming part 8 includes an RF power source 81, a matching part 82, and a power supply line 83. The RF power source 81 is a power source that generates RF power. The RF power has a frequency suitable for formation of a plasma. The frequency of the RF power is, for example, within a range from 450 KHz in the low frequency band to 2.45 GHz in the microwave band. The RF power source 81 is connected to the main body 31 of the showerhead 3 via the matching part 82 and the power supply line 83. The matching part 82 includes a circuit for matching the load impedance with the internal impedance of the RF power source 81.

The plasma forming part 8 has been described as supplying RF power to the showerhead 3 serving as the upper electrode. However, these are non-limiting features. The plasma forming part 8 may be configured to supply RF power to the holder 2 serving as the lower electrode. The plasma forming part 8 is not limited to forming a capacitively coupled plasma, and may be configured to form other plasmas, such as an inductively coupled plasma, a remote plasma, and the like.

The controller 9 is, for example, a computer, and includes a Central Processing Unit (CPU), a Random Access Memory (RAM), a Read Only Memory (ROM), an auxiliary storage device, and the like. The CPU operates based on a program stored in the ROM or the auxiliary storage device to control the operation of the film forming apparatus. The controller 9 controls the gas exhaust part 4, the gas supply 5, and the plasma forming part 8, and to perform control for performing the film forming method shown in FIG. 2.

The controller 9 includes an electronic circuit, such as a CPU, a Field Programmable Gate Array (FPGA), an Application Specific Integrated Circuit (ASIC), and the like, and performs various control operations described in this specification by executing instruction codes stored in the memory or by being designed as a circuit for a special application.

The embodiments of the film forming method and the film forming apparatus of the present disclosure have been described. However, the present disclosure is not limited to the above embodiments and the like. Various changes, modifications, substitutions, additions, deletions, and combinations are applicable within the scope of the claims. Naturally, these also fall within the technical scope of the present disclosure.

According to one embodiment of the present disclosure, a silicon nitride film excellent in wet etching resistance and embeddability can be formed in a recess in a substrate surface.

What is claimed is:

1. A film forming method, comprising:
forming a silicon nitride film in a recess in a substrate surface,
wherein the forming of the silicon nitride film includes:
supplying an adsorption-inhibiting gas for inhibiting adsorption of a silicon-containing gas to the substrate surface in a form of a plasma;
supplying the silicon-containing gas to the substrate surface; and
supplying a nitriding gas for nitriding an adsorbate of the silicon-containing gas to the substrate surface in a form of a plasma,
wherein the nitriding gas contains N₂ gas,
wherein the forming of the silicon nitride film includes supplying an adsorption-promoting gas for promoting adsorption of the silicon-containing gas to the substrate surface, and
wherein performing a process including: the supplying of the adsorption-inhibiting gas; the supplying of the silicon-containing gas; and the supplying of the nitriding gas one or more times, and performing the supplying of the adsorption-promoting gas one or more times are performed a plurality of times repeatedly.

2. The film forming method according to claim 1,
wherein the adsorption-promoting gas contains an NH₂ group.

3. The film forming method according to claim 2,
wherein the adsorption-promoting gas contains at least one selected from NH₃ gas, N₂H₄ gas, N₂H₂ gas, CH₃NHNH₂ gas, and CH₃NH₂ gas.

4. The film forming method according to claim 1,
wherein the forming of the silicon nitride film includes forming a plasma of a modifying gas for modifying the adsorbate of the silicon-containing gas and supplying it to the substrate surface, and
wherein the modifying gas contains H₂ gas.

5. The film forming method according to claim 4,
wherein the supplying of the modifying gas is performed after the supplying of the silicon-containing gas and before the supplying of the nitriding gas.

6. The film forming method according to claim 4,
wherein the modifying gas further contains an inert gas.

7. The film forming method according to claim 1,
wherein the forming of the silicon nitride film includes supplying the adsorption-promoting gas to the substrate surface in a form of a plasma.

8. The film forming method according to claim 1,
wherein the forming of the silicon nitride film includes:
supplying the adsorption-promoting gas to the substrate surface without forming a plasma thereof; and
supplying the adsorption-promoting gas to the substrate surface in a form of a plasma.

9. The film forming method according claim 8,
wherein the forming of the silicon nitride film includes performing a plurality of times repeatedly, the supplying of the adsorption-promoting gas to the substrate surface without forming a plasma thereof, and the supplying of the adsorption-promoting gas to the substrate surface in a form of a plasma.

10. The film forming method according to claim 1,
wherein the adsorption-inhibiting gas contains at least one of a halogen gas, a non-halogen gas, or a mixture gas of the halogen gas and the non-halogen gas.

11. The film forming method according to claim 10,
wherein the forming of the silicon nitride film includes:
supplying the mixture gas of the halogen gas and the non-halogen gas to the substrate surface in a form of a plasma; and
supplying only one of the halogen gas or the non-halogen gas to the substrate surface in a form of a plasma.

12. The film forming method according to claim 11,
wherein the forming of the silicon nitride film includes alternately performing, a plurality of times repeatedly, the supplying of the mixture gas of the halogen gas and the non-halogen gas to the substrate surface in a form of a plasma, and the supplying of only one of the halogen gas or the non-halogen gas to the substrate surface in a form of a plasma.

13. The film forming method according to claim 10,
wherein the halogen gas is Cl₂ gas, and the non-halogen gas is N₂ gas.

14. The film forming method according to claim 1,
wherein the silicon-containing gas contains silicon and halogen.

15. A film forming apparatus, comprising:
a processing vessel configured to house a substrate;
a holder configured to hold the substrate in the processing vessel;
a gas supply configured to supply a gas into the processing vessel;
a plasma forming part configured to form a plasma of the gas supplied by the gas supply; and
a controller including a processor and a memory, and configured to control the gas supply and the plasma forming part,
wherein the controller performs control for performing the film forming method of claim 1.
